(19) United States
(12) Patent Application Publication
(10) Pub. No.: US 2006/0049717 A1
(43) Pub. Date: Mar. 9, 2006

(54) Transformer

(76) Inventor: Frank Liebenow, Jefferson, SD (US)

Correspondence Address: LARSON AND LARSON, 11199 69TH STREET NORTH, LARGO, FL, 33773, US

(21) Appl. No.: 10/935,849

(22) Filed: Sep. 8, 2004

(51) Int. Cl. H01L 41/107

(52) U.S. Cl. 310/318

(57) ABSTRACT

A transformer is describe, whereas the primary of the transformer may be a piezoelectric element coupled to a magnetized material that moves in response to electric voltages applied to the primary and such movement is converted to a second electric voltage in a nearby secondary coil. Likewise, the primary may be a coil whereas a voltage applied to said coil may induce movement of a magnetic material near said coil, said movement may then be coupled to a piezoelectric element, generating a voltage from said movement.

### FIELD OF THE INVENTION

The present invention generally relates to the field of power transformation, in particular a transformer with a transducer as a primary or secondary and a magnetic winding as the secondary or primary. The present invention relates to an apparatus for the conversion of power providing isolation as well as voltage conversion.

### BRIEF DESCRIPTION OF THE RELATED ART

There are several forms of transformer today. In general, a transformer is useful in many situations. For example, converting between one voltage and another; isolating voltages; and floating an input source. Most transformers consist of two or more coils of wire wound around a magnetic core. The input coil is called the primary and the output coil(s) is called the secondary. By applying an alternating current on the primary coil, a magnetic field is created upon the magnetic core, inducing an output voltage on the secondary core. By applying an AC voltage on the primary, a second AC voltage will result on the secondary. Depending on the ratio of the number of turns in the primary to the number of turns in the secondary, the transformer may either step-up or step-down the voltage. Because there is substantially no electrical conductance between the primary and secondary, the output voltage on the secondary will be electrically isolated from the primary. Besides isolating the input from the output, increases or decreases in voltage potential between the primary and secondary can be realized. Some magnetic transformers have solid iron cores, some have laminated cores, sometimes, the magnetic interface is between the primary and secondary is not a magnetic core, perhaps just a primary and a secondary winding in close proximity to each other. Sometimes the core is a continuous circle of magnetic material, known as a torroid transformer. Magnetic transformers are useful in a wide range of voltage conversion.

Another technology for transforming electricity is a piezoelectric transformer. These transformers use one piezoelectric element with three or four terminals to form a transformer. A piezoelectric transformer is a type of AC voltage multiplier. A piezoelectric transformer uses acoustic coupling to couple an input side to an output side. An input voltage is applied across a short length of a bar of piezoelectric material, creating an alternating stress in the bar and causing the whole bar to vibrate. The vibration frequency may be selected to be the resonant frequency of the bar, typically in the 100 kilohertz to 1 megahertz range. An output voltage is then generated across another section of the bar by piezoelectric effect. Step-up ratios of more than 1000:1 and step down ratios of 1:10 may be possible.

In practice, these transformers usually provide an input-to-output voltage range of possibly 0.1 to 1000. Given a fixed input voltage of X volts, a transformer could be designed to generate output voltages from X/10 volts to 1000X volts. This range is somewhat limiting. For example, if working with AC line voltages, the lowest secondary voltage might be around 12 VAC in the United States (120V/10), and possible 22V (220/10) in counties where the standard power source is 220V. Magnetic transformers don't share this limitation, in that, depending on the ratio of windings; almost infinite step-up or step-down ratios are possible. For example, there are transformers that accept 120 VAC on their primary and output 5 VAC on their secondary. There are photoflash transformers for initiating the flow of current in Xenon flash tubes that generate many thousands of volts from a very low voltage input pulse, perhaps 5 volts.

Although the aforementioned transformers provide different methods to convert one electrical voltage to another, each has its limitations. Magnetic transformers are bulky, have higher mass and are inefficient. Piezoelectric transformers have less mass, but don't provide a very dynamic range of voltage increase or decrease and do not provide isolation.

### SUMMARY OF THE INVENTION

A solution to the problems described and other problems is a transformer of the resent invention. In this invention, either the primary or the secondary of the transformer is made from a transducer and the other (secondary or primary) is made from a magnetic coil. In an embodiment of the present invention, both the primary and secondary are made from transducers, possibly separated by a rigid energy transfer member. In another embodiment, the transducer is a piezoelectric element. In another embodiment of the present invention, the transducer is a micro machine and the secondary is either a piezoelectric element or a magnetic coil. An example of such a micro machine is the micro-scale motor developed by a UC Berkeley physicist, the first nano-scale motor—a gold rotor on a nanotube shaft that is small enough to ride on the back of a virus.

In another embodiment of the present invention, the primary of the transformer is a piezoelectric element, or possibly a micro machine. The piezoelectric element or micro machine is coupled to a magnetized material or permanent magnet, for example, magnetized iron. The magnetized material or permanent magnet is disposed near or within a secondary coil, perhaps said secondary coil is windings of wire or a loop of paths on a printed circuit board or integrated circuit substrate. As a voltage is applied to the primary, the piezoelectric element deforms or the micro machine creates motion, moving the magnetized material within or near the secondary coil, thus producing an electric field within the secondary coil. Since there is no direct connection between the primary and the secondary, this invention may also provide isolation between the primary and the secondary.

In another embodiment of the present invention, the primary of the transformer is a piezoelectric element or micro machine. The piezoelectric element or micro machine is coupled to a magnetized material, for example, magnetized iron. The magnetized material is then disposed near or within a plurality of secondary coils. As a voltage is applied to the primary, the piezoelectric element deforms or the micro machine creates motion, moving the magnetized material within or near the secondary coils, producing an electric field within each of the plurality of the secondary coils. Since there is no direct connection between the primary and the secondary(s), this invention may also provide isolation between the primary and the secondary.

In another embodiment of this invention, a primary piezoelectric element is coupled to a secondary piezoelectric element with an energy transfer member, preferable a stiff material such as plastic, nylon, wood, hard rubber, etc. If the transfer member is made from an insulator such as nylon, it may allow energy in the form of force generated by an AC voltage applied to the primary piezoelectric element to transfer to the secondary piezoelectric element, producing an electric voltage on the secondary in response to this movement. This transfer member may provide isolation between the primary and the secondary while allowing energy to transfer between them.

In another embodiment of the present invention, the primary of the transformer is a conductive coil. A magnetic material, perhaps iron or steel, is then disposed near or within the conductive coil. As a voltage is applied to the primary, the conductive coil generates a magnetic field, moving the magnetic material, thus producing movement much like that of a magnetic doorbell. The magnetic material is coupled to a piezoelectric element and this movement is converted into an electrical voltage in response to the stimulus from the movement of the magnetic material by the piezoelectric effect. Since there is no direct connection between the primary and the secondary, this invention provides isolation between the primary and the secondary. In a further embodiment of this invention, the magnetic material is coupled to the piezoelectric element with an insulative material, preferable a stiff material such as plastic, nylon, wood, hard rubber, etc. The insulative material allows the piezoelectric element to move as the magnetic material moves in response to changes in input voltage and transfers energy to the piezoelectric element, producing an electric voltage on the secondary in response to this movement. This insulative material may provide even greater isolation between the primary and the secondary.

In another embodiment, a piezoelectric-piezoelectric transformer, a voltage is applied to the first piezoelectric-electric element, causing it to change shape, exerting a force on a coupling between that element and a second piezoelectric element and therefore, placing a force on the second piezoelectric element. In response to the force, the second piezoelectric element is deformed, causing a second voltage on its output. By selecting a certain size piezoelectric element for the primary and secondary, voltage increases or decreases can be accomplished. Likewise, if the coupling member is an insulator, then the primary will be isolated from the secondary. This type of transformer is useful for converting voltages within a limited range, because of the limitations on piezoelectric element size and structure.

It is to be understood that both the forgoing general description and the following detailed description are exemplary only and are not restrictive of the invention as claimed. The general functions of this invention may be combined in different ways to provide the same functionality while still remaining within the scope of this invention.

### BRIEF DESCRIPTION OF THE DRAWINGS

The numerous advantages of the present invention may be better understood by those skilled in the art by reference to the accompanying figures in which:

FIG. 1 shows the prior art, a transformer utilizing a single piezoelectric element to transform an input voltage into a, normally, higher output voltage.

FIG. 2 shows a transformer of the present invention utilizing a transfer element to couple a primary piezoelectric element to a secondary piezoelectric element.

FIG. 3. shows a transformer of the present invention utilizing a piezoelectric element as a primary and one conductive coil as a secondary.

FIG. 4. shows a transformer of the present invention utilizing a piezoelectric element as a primary and two conductive coils as secondaries.

FIG. 5. shows a transformer of the present invention utilizing a conductive coil as the primary and a piezoelectric element as the secondary.

FIG. 6. shows a transformer of the present invention utilizing a micro machine as a primary and one conductive coil as a secondary.

### DETAILED DESCRIPTION

Reference will now be made in detail to the presently discussed embodiment of the invention, an example of which is illustrated in the accompanying drawings.

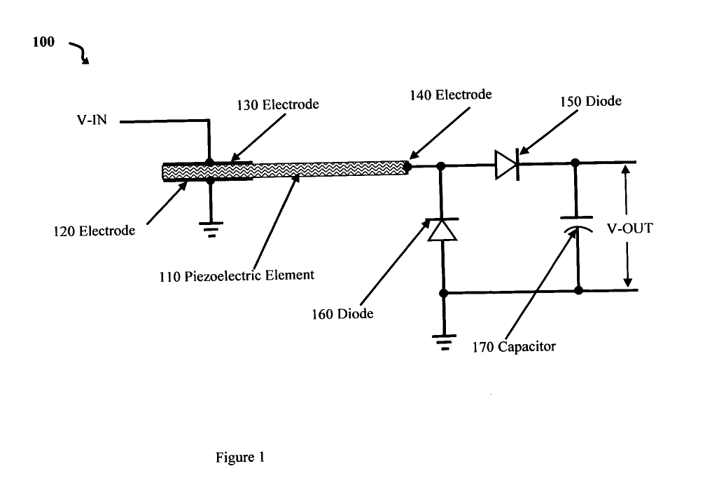

Referring now to FIG. 1, a transformer utilizing a single piezoelectric element to transform an input voltage into a, normally, higher output voltage. This form of piezoelectric transformer is known in the industry, for example, Technical Publication TP-244, “Piezoelectric Transformers,” Morgan Electro Ceramics, describes this device. These transformers use one piezoelectric element 110 with three or four terminals to form a transformer. In FIG. 1, three terminals are shown: common electrode 120, input electrode 130 and output electrode 140. A piezoelectric transformer is a type of AC voltage multiplier. This piezoelectric transformer uses acoustic coupling to couple an input side to an output side. An input voltage is applied across the input electrode 130 and the common electrode 120, creating an alternating stress in the bar and causing the whole bar to vibrate. The vibration frequency may be selected to be the resonant frequency of the bar, typically in the 100 kilohertz to 1 megahertz range. An output voltage is then generated between the common electrode 120 and the output electrode 140 by piezoelectric effect. Step-up ratios of more than 1000:1 and step down ratios of 1:10 may be possible. For completeness, a voltage doubler consisting of diode 150, diode 160 and capacitor 170 are shown as a typical method of filtering and stepping up the output voltage even further. It should be noted that, since common electrode 120 is common to both the input and the output, this transformer does not provide any isolation. If a four terminal piezoelectric transformer was implemented, then the output electrodes could be different from the input electrodes and some isolation may be achieved, but would be limited to the resistance and breakdown voltage of the piezoelectric material.

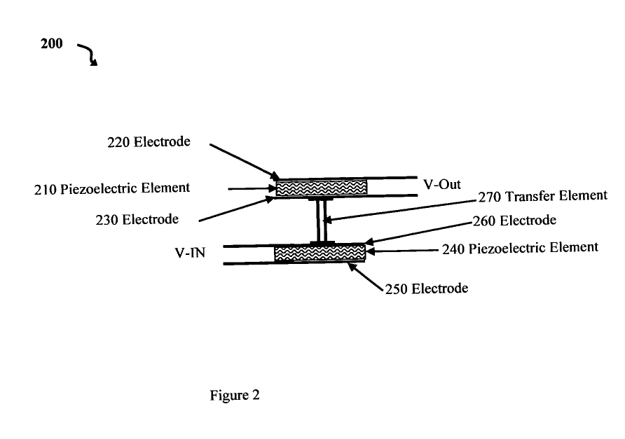

Referring now to FIG. 2, a transformer of the present invention utilizing two piezoelectric elements to transform an input voltage into a higher, lower or similar output voltage. In this embodiment, the input voltage, an alternating current, is provided across electrode 250 and electrode 260, causing piezoelectric element 240 to vibrate. The energy produced by this vibration is transferred across transfer element 270 to a second piezoelectric element 210. This transfer element can be fabricated from most any material, but it is preferred to be a stiff material to better transfer energy from the first piezoelectric element 240 to the second piezoelectric element 210. If this material is an insulator such as nylon, wood, plastic or ceramic; isolation and insulation between the input (first piezoelectric element) and the output (second piezoelectric element) would be accomplished. The output voltage is created across the second piezoelectric element 210 on electrodes 220 and 230 in response to the vibration energy. This form of transformer is more efficient if the bottom of piezoelectric element 250 and the top of piezoelectric element 210 are structurally confined so that as piezoelectric element 240 expands from the input current, piezoelectric element 210 is compressed. This structural confinement may be a bracket or enclosure that holds both elements securely and, if isolation is desired, is perhaps an insulator.

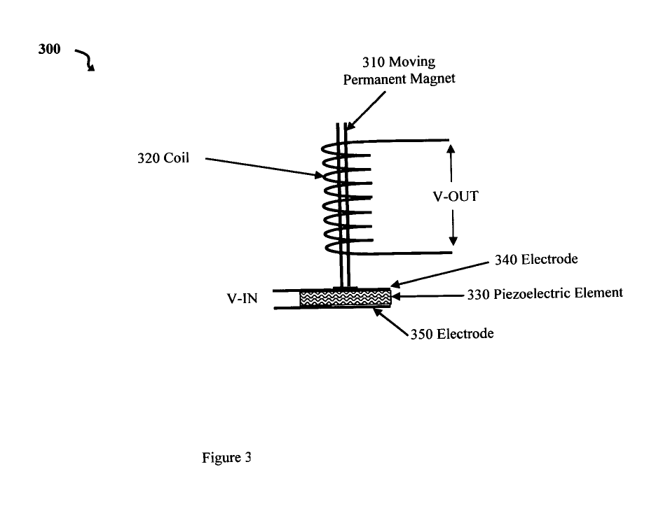

Referring now to FIG. 3, a transformer of the present invention utilizing one piezoelectric element as a primary and a coil as a secondary. In this embodiment, an alternating current presented across piezoelectric element 330 on electrodes 340 and 350 cause piezoelectric element 330 to expand and contract through the piezoelectric effect. Piezoelectric element 330 is connected to a permanent magnet 310 that moves through coil 320 in response to the motion created by piezoelectric element 330. Coil 320 may be a winding of insulated wire on a core, or bobbin and, preferably, may surround the permanent magnet 310. The output voltage, V-OUT, may be taken from the ends of the wire in coil 320. Although, for stand-alone or mountable transformers, coil 320 may be made from enameled copper wire as normally used in transformers, most any coil of wire where the turns are insulated from each other will suffice, for example, Teflon coated wire, bare wired insulated by an air-gap or a loop created on an integrated circuit substrate or printed circuit board. The greater number of turns in coil 320, the higher the output voltage.

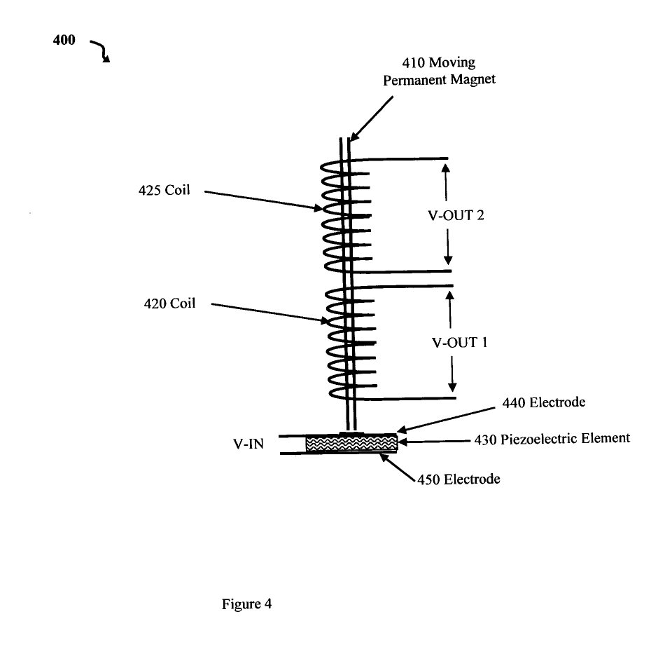

Referring now to FIG. 4, a transformer of the present invention utilizing one piezoelectric element as a primary and a plurality of coils as a secondary. In this embodiment, an alternating current presented across piezoelectric element 430 on electrodes 440 and 450 cause piezoelectric element 430 to expand and contract through the piezoelectric effect. Piezoelectric element 430 is connected to a permanent magnet 410 that moves in proximity to coil 420 and coil 425 in response to the motion created by piezoelectric element 430. Coils 420 and 425 may be winds of insulated wire on a core, or bobbin and, preferably, may surround the permanent magnet 410. The output voltage, V-OUT, may be taken from the ends of the wire in each of coils 420 and 425. Although, for stand-alone or mountable transformers, coils 420 and 425 may be made from enameled copper wire as normally used in transformers, most any coil of wire where the turns are insulated from each other will suffice, for example, Teflon coated wire, bare wired insulated by an air-gap or a loop created on an integrated circuit substrate or printed circuit board. The greater number of turns in each of coils 420 and 425, the higher the output voltage generated over each coil.

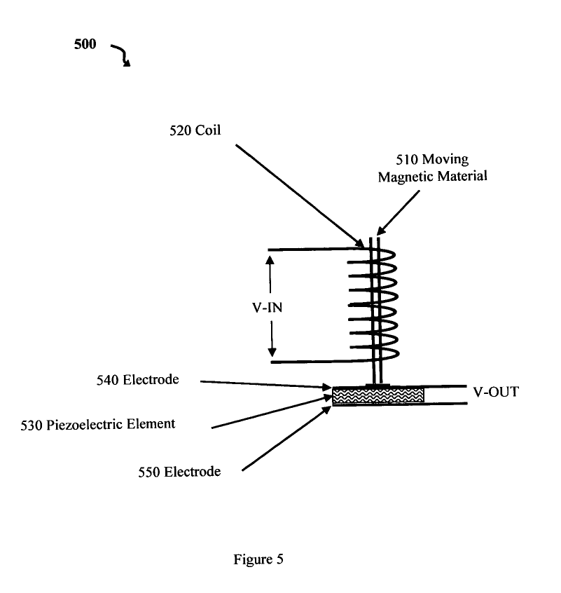

Referring now to FIG. 5, a transformer of the present invention utilizing one piezoelectric element as a secondary and coil as a primary. In this embodiment, an alternating current is presented across coil 520. Magnetic material 510 moves in response to this alternating current, much like a core within a solenoid. Magnetic material 510 is attached to piezoelectric element 530, transferring this energy of movement into a force exerted upon piezoelectric element 530. This force is converted to electricity and is accumulated on electrodes 540 and 550 as an output voltage. Although, for stand-alone or mountable transformers, coil 520 may be made from enameled copper wire as normally used in transformers and solenoids, most any coil of wire where the turns are insulated from each other will suffice, for example, Teflon coated wire, bare wired insulated by an air-gap or a loop created on an integrated circuit substrate or printed circuit board. For best efficiency, coil 520 and the bottom side of piezoelectric element 530 should be structurally confined so increases in the magnetic field created by coil 520 will create the greatest amount of force on piezoelectric element 530. Although a single input coil 520 is shown, many configurations of input coils may be utilized, for example, a center-tapped coil for push-pull operation. Additionally, extra windings may be present to provide oscillation feedback or similar.

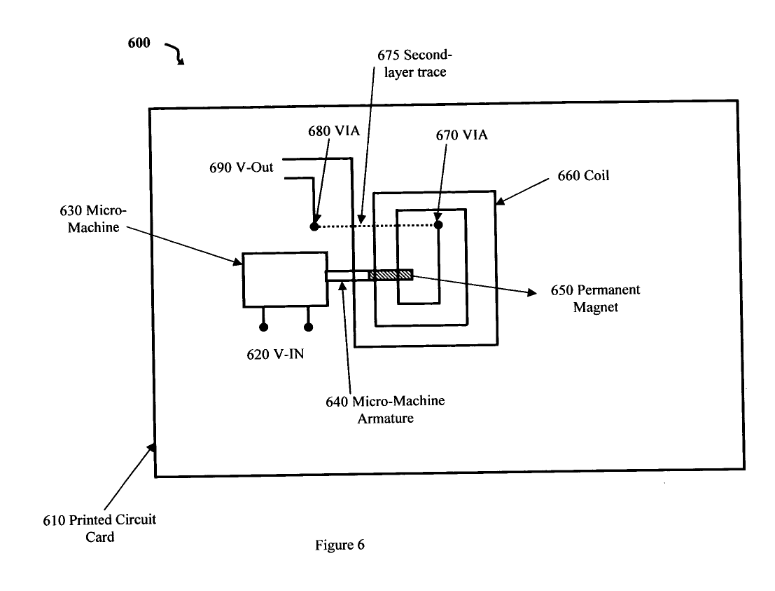

Referring now to FIG. 6, a transformer of the present invention utilizing one piezoelectric element as a secondary and coil as a primary. In this embodiment, an alternating current is presented on the input 620 to micro machine 630. Armature 640 moves in response to this current and causes permanent magnet 650 to in proximity to coil 660, inducing a flow of current within coil 660. As shown, coil 660 may be a loop made from printed circuit board paths. In this example, the inside end of the loop passes through a via 670 to a path on a different layer 675 then back up to the first layer through via 680, presenting the output voltage at 690. Although a single output coil 660 is shown, many configurations of output coils may be utilized, for example, a center-tapped coil for full-wave operation. Additionally, extra windings may be present to provide oscillation feedback or similar.

It is believed that the present invention and many of its attendant advantages will be understood by the forgoing description. It is also believed that it will be apparent that various changes may be made in the form, construction and arrangement of the components thereof without departing from the scope and spirit of the invention or without sacrificing all of its material advantages. The form herein before described being merely an explanatory embodiment thereof. It is the intention of the following claims to encompass and include such changes.

What is claimed is:

1. A transformer comprising:
a primary circuit comprising a transducer element, said tranducer element having at least two electrodes attached for input of an alternating electric current;
at least one secondary circuit comprising a conductive coil; and
a permanent magnet attached to said transducer element, said permanent magnet positioned in proximity to said conductive coil;
whereas said alternating electric current causes said transducer element to expand and contract, moving said permanent magnet in proximity to said conductive coil, inducing a flow of electricity in said conductive coil.

2. A transformer as claimed in claim 1, wherein said transducer element is a piezoelectric element.

3. A transformer as claimed in claim 1, wherein said transducer element is a micro machine.

4. A transformer as claimed in claim 1, wherein said conductive coil is a winding of enameled wire wound around a form and said permanent magnet is disposed substantially within said form.

5. A transformer as claimed in claim 1, wherein said conductive coil has a plurality of taps for producing a plurality of output voltages.

6. A transformer as claimed in claim 1, wherein said conductive coil is constructed from conductive paths of a printed circuit board.

7. A transformer as claimed in claim 1, wherein said conductive coil is constructed from conductive paths on an integrated circuit substrate.

8. A transformer comprising:
a primary circuit comprising a micro machine, said micro machine having at least two electrodes attached for input of an alternating electric current;
at least one secondary circuit comprising a conductive coil; and
a permanent magnet attached to said micro machine, said permanent magnet positioned in proximity to said conductive coil;
whereas said alternating electric current causes said micro machine to move said permanent magnet in proximity to said conductive coil, inducing a flow of electricity in said conductive coil.

9. A transformer as claimed in claim 8, wherein said alternating electric current alternates at a frequency from 1 Khz to 100 Khz.

10. A transformer as claimed in claim 8, wherein said conductive coil is a winding of enameled wire wound around a form and said permanent magnet is disposed substantially within said form.

11. A transformer as claimed in claim 8, further comprising a second conductive coil, said second conductive coil positioned in proximity to said conductive coil.

12. A transformer as claimed in claim 8, wherein said conductive coil has a plurality of taps for producing a plurality of output voltages.

13. A transformer as claimed in claim 8, wherein said conductive coil is a coil constructed from conductive paths of a printed circuit board.

14. A transformer as claimed in claim 8, wherein said conductive coil is constructed from conductive paths on an integrated circuit substrate.

15. A method of transforming alternating current comprising:
applying a first alternating current to a piezoelectric element, said piezoelectric element connected to a magnet, said magnet disposed in proximity to a conductive coil; and
outputting a second alternating current from said conductive coil.

16. A method of transforming alternating current as in claim 15, whereas said conductive coil is a coil of wire and said magnet is disposed substantially within said coil of wire.

17. A method of transforming alternating current as in claim 15, whereas said conductive coil is a path on a printed circuit board.

18. A method of transforming alternating current as in claim 15, whereas said conductive coil is a path on an integrated circuit substrate.

19. A method of transforming alternating current comprising:
applying a first alternating current to a first piezoelectric element, said first piezoelectric element connected to a second piezoelectric element; and
outputting a second alternating current from said second piezoelectric element.

20. A method of transforming alternating current as in claim 19, wherein said first piezoelectric element is connected to said second piezoelectric element with an insulative material.

21. A method of transforming alternating current as in claim 20, wherein said insulative material is chosen from a group consisting of nylon, wood, and plastic.

22. A tranformer comprising:
a primary circuit comprising a conductive coil;
a magnetic material disposed in proximity to said electric coil; and
a secondary circuit comprising a piezoelectric element, said piezoelectric element coupled to said magnetic material, whereas an alternating current applied to said primary circuit causes said magnetic material to move, exerting a force upon said piezoelectric element, there as creating a voltage across said secondary circuit.

23. A transformer as in claim 22, wherein said conductive coil is wound on a form and said magnetic material is substantially disposed within said form.

24. A transformer as in claim 20, wherein said magnetic material is chosen from a group consisting of iron and steel.
